(19) United States
(12) Patent Application Publication
(10) Pub. No.: US 2013/0105301 A1
(43) Pub. Date: May 2, 2013

(54) TRANSPARENT CONDUCTIVE FILM AND MANUFACTURING METHOD THEREFOR

(71) Applicants: Yuka Yamazaki, Ibaraki-shi (JP); Tomotake Nashiki, Ibaraki-shi (JP); Hideo Sugawara, Ibaraki-shi (JP)

(72) Inventors: Yuka Yamazaki, Ibaraki-shi (JP); Tomotake Nashiki, Ibaraki-shi (JP); Hideo Sugawara, Ibaraki-shi (JP)

(73) Assignee: NITTO DENKO CORPORATION, Ibaraki-shi, Osaka (JP)

(21) Appl. No.: 13/808,478

(22) PCT Filed: Jul. 6, 2011
(86) PCT No.: PCT/JP2011/065478

§ 371 Date: Jan. 4, 2013

(30) Foreign Application Priority Data
Jul. 6, 2010 (JP) 2010-154219

(51) Int. Cl. C23C 14/08

(52) U.S. Cl. CPC C23C 14/086
USPC 204/192.29

(57) ABSTRACT

An object of the present invention is to manufacture a long transparent conductive film comprising a transparent film substrate and a crystalline indium composite oxide film formed on the transparent film substrate. The manufacturing method of the present invention includes an amorphous laminate formation step of forming an amorphous film of an indium composite oxide containing indium and a tetravalent metal on the long transparent film substrate with a sputtering method, and a crystallization step of continuously feeding the long transparent film substrate on which the amorphous film is formed into a furnace and crystallizing the amorphous film. The indium composite oxide preferably contains more than 0 parts by weight and 15 parts by weight or less of the tetravalent metal based on 100 parts by weight of the total of indium and the tetravalent metal.

### TECHNICAL FIELD

The present invention relates to a transparent conductive film comprising a transparent film substrate and a crystalline transparent conductive thin film formed on the transparent film substrate, and a manufacturing method thereof.

### BACKGROUND ART

A transparent conductive film comprising a transparent film substrate and a transparent conductive thin coat formed on the transparent film substrate has been broadly used in solar cells, transparent electrodes for inorganic EL elements and organic EL elements, magnetic wave shielding materials, touch panels, etc. Especially, the mounting rate of a touch panel to cellular phones, portable game machines, etc. has increased in recent years, and the demand for a transparent conductive film for a capacitive touch panel that enables multipoint sensing has rapidly expanded.

A transparent conductive film that is used in a touch panel, etc. has been broadly used in which a conductive metal oxide film such as an indium tin composite oxide (ITO) is formed on a flexible transparent substrate such as a polyethylene terephthalate film. For example, an ITO film is generally formed with a sputtering method in which an oxide target having the same composition as that of the ITO film that is formed on the substrate or a metal target including an In—Sn alloy is used, and an inert gas (Ar gas) by itself and a reactive gas such as oxygen are introduced as necessary.

When an indium composite oxide film such as ITO is formed on a transparent film substrate including a polymer molding such as a polyethylene terephthalate film, sputtering cannot be performed at high temperature because there is a restriction due to the heat resistance of the substrate. For this reason, the indium composite oxide film immediately after it is formed is an amorphous film (apart of the film may be also crystallized). Such an amorphous indium composite oxide film has problems such that the film has strong yellow tints and the transparency thereof becomes poor, and that a resistance change after a humidification and heating test is large.

For this reason, it is generally performed that an amorphous film is formed on a substrate including a polymer molding, and then it is heated under an oxygen atmosphere in air to convert the amorphous film to a crystalline film (for example, see Patent Document 1). With this method, advantages can be brought such that the transparency of the indium composite oxide film improves, that a resistance change after the humidification and heating test becomes small and that the reliance to humidification and heating improves, etc.

A step of manufacturing a transparent conductive film comprising a transparent film substrate and a crystalline indium composite oxide film formed on the transparent film substrate is divided broadly into a step of forming an amorphous indium composite oxide film on the transparent substrate and a step of crystallizing the indium composite oxide film by heating. A method for forming a thin film on a substrate surface using a winding type sputtering apparatus while consecutively allowing a long substrate to run has been conventionally adopted to form an amorphous indium composite oxide film. That is, an amorphous indium composite oxide film is formed on a substrate with a roll-to-roll method, and a roll of a long transparent conductive laminate is formed.

On the other hand, the step of crystallizing the indium composite oxide film afterwards is performed with a batch manner after a sheet having a prescribed size is cut out from the long transparent conductive laminate on which the amorphous indium composite oxide film is formed. Such crystallization of the indium composite oxide film with a batch manner is mainly caused by the fact that a long time is necessary to crystallize the amorphous indium composite oxide film. To crystallize the indium composite oxide, heating under a temperature atmosphere of, for example, about 100 to 150° C. for a few hours is necessary. However, it is necessary to make the length of a furnace large or to make the feeding speed of the film small in order to perform such a long time heating step with a roll-to-roll method. The former needs a huge facility, and the latter needs to largely sacrifice productivity. For this reason, the crystallization of the indium composite oxide film such as ITO has been considered to be beneficial in respects of cost and productivity when it is performed by heating the sheet with a batch manner, and it has been considered to be an unsuitable step for a roll-to-roll method.

On the other hand, supplying a long transparent conductive film comprising a transparent film substrate and a crystalline indium composite oxide film formed on the transparent film substrate is largely beneficial in the formation of a touch panel afterwards. For example, when a roll of such a long film is used, a step of forming a touch panel afterwards is simplified because it can be performed with a roll-to-roll method, and this can contribute to productivity and lowering of cost. After the crystallization of the indium composite oxide film, a step of forming a touch panel can be also performed subsequently without winding up into a roll.

### PRIOR ART DOCUMENT

### Patent Document

Patent Document 1: JP-B-03-15536

### DISCLOSURE OF THE INVENTION

### Problems to be Solved by the Invention

In view of the above-described circumstances, an object of the present invention is to provide a long transparent conductive film comprising a transparent film substrate and a crystalline indium composite oxide film formed on the transparent film substrate.

### Means for Solving the Problems

In view of the above-described object, the present inventors have attempted to introduce a roll on which an amorphous indium composite oxide film is formed into a furnace while it is in a state of being wound to crystallize the film. However, with such a method, defects occur such that winding and tightening that occur in the roll caused by the dimensional change of the substrate film, etc. cause deformation such as wrinkles in the transparent conductive film, and that the film quality in the film surface becomes non-uniform.

Further investigation has been performed in order to obtain a long transparent conductive film on which a crystalline indium composite oxide film is formed. As a result, it is found that a step of crystallizing the indium composite oxide film can be performed with a roll-to-roll method under prescribed conditions to obtain a transparent conductive film having the same level of characteristics as a crystalline indium composite oxide film that is obtained by heating with a conventional batch manner. The finding has led to completion of the present invention.

That is, the present invention is a method for manufacturing a long transparent conductive film comprising a transparent film substrate and a crystalline indium composite oxide film formed on the transparent film substrate, and the method includes an amorphous laminate formation step of forming an amorphous film of an indium composite oxide containing indium and a tetravalent metal on the long transparent film substrate with a sputtering method, and a crystallization step of continuously feeding the long transparent film substrate on which the amorphous film is formed into a furnace and crystallizing the amorphous film. The indium composite oxide contains more than 0 parts by weight and 15 parts by weight or less of the tetravalent metal based on 100 parts by weight of the total of indium and the tetravalent metal.

When a metal target is used as a target for sputter film formation, the amount of a tetravalent metal atom in the metal target is 15 parts by weight or less based on the total weight of the In atom and the tetravalent metal atom to form the indium composite oxide having the above-described composition.

In the amorphous laminate formation step, an amorphous indium composite oxide film, the crystallization of which can be completed by heating at a temperature of 180° C. for 60 minutes, is preferably formed on the transparent film substrate. For this reason, the inside of a sputtering apparatus is preferably vented to have a vacuum of 1×10⁻³ Pa or less before the amorphous film is formed.

In the crystallization step, the temperature inside the furnace is preferably 120 to 260° C. The heating time in the crystallization step is preferably 10 seconds to 30 minutes. A change rate of the film length in the crystallization step is, for example, preferably as small as +2.5% or less. From the viewpoint of making the change rate of the film length small, the stress of the film in the feeding direction in the crystallization step is preferably 1.1 to 13 MPa.

### Effect of the Invention

According to the present invention, a long transparent conductive film on which a crystalline indium composite oxide film is formed can be effectively manufactured because the crystallization of the amorphous film can be performed while feeding the film. Such a long film is wound up into a roll once, and then it is used to form a touch panel, etc. Alternatively, a next step such as a step of forming a touch panel can be performed subsequently to the crystallization step. Especially, the crystallization step in the present invention can be made to be a heating step in a relatively short time because an amorphous film that can be crystallized by heating in a short time is formed in the amorphous laminate formation step. For this reason, the crystallization step is optimized, and the productivity of the transparent conductive film can be improved. In addition, the feeding tension of the film is controlled in the crystallization step and the elongation of the film is suppressed to obtain a transparent conductive film of low resistance, and high heating and humidification reliance with high productivity.

### BRIEF DESCRIPTION OF THE DRAWINGS

FIG. 1 is a schematic sectional view showing a lamination configuration of a transparent conductive film according to one embodiment.

FIG. 2 is a graph in which a relationship is plotted between the maximum value of a dimensional change rate in a TMA measurement and the resistance change of a crystalline ITO film.

FIG. 3 is a graph in which a relationship is plotted between the difference of dimensional change rates before and after the crystallization is performed while feeding a film and the resistance change of a crystalline ITO film.

FIG. 4 is a graph in which a relationship is plotted between the maximum value of a dimensional change rate in a TMA measurement and the difference of dimensional change rates before and after the crystallization is performed while feeding a film.

FIG. 5 is a conceptual drawing to illustrate an outline of a crystallization step by a roll-to-roll method.

### MODE FOR CARRYING OUT THE INVENTION

First, the configuration of a transparent conductive film according to the present invention will be described. As shown in FIG. 1 (b), a transparent conductive film 10 has a configuration in which a crystalline indium composite oxide film 4 is formed on a transparent film substrate 1. Anchor layers 2 and 3 may be provided between the transparent film substrate 1 and the crystalline indium composite oxide film 4 for the purpose of improving adhesion between the substrate and the indium composite oxide film, for controlling reflection characteristics with a refractive index, etc.

First, an amorphous indium composite oxide film 4′ is formed on the substrate 1, the amorphous film is heated together with the substrate, and it is crystallized to form the crystalline indium composite oxide film 4. Conventionally, the crystallization step has been performed by heating a sheet with a batch manner. However, in the present invention, a roll of a long transparent conductive film 10 is obtained because the heating and the crystallization are performed while feeding a long film.

In the present specification, regarding a laminate comprising a substrate and an indium composite oxide film formed on the substrate, a laminate in which the indium composite oxide film is before crystallization may be noted as “an amorphous laminate”, and a laminate in which the indium composite oxide film is crystallized may be noted as “a crystalline laminate.”

Each step of the method for manufacturing a long transparent conductive film will be described in order below. First, a long amorphous laminate 20 comprising the transparent film substrate 1 and the amorphous indium composite oxide film 4′ formed on the transparent film substrate 1 is formed (an amorphous laminate formation step). In the amorphous laminate formation step, the anchor layers 2 and 3 are provided on the substrate 1 as necessary, and the amorphous indium composite oxide film 4′ is formed thereon.

### (Transparent Film Substrate)

The material of the transparent film substrate 1 is not especially limited as long as it has flexibility and transparency, and appropriate materials can be used. Specific examples thereof include a polyester resin, an acetate resin, a polyethersulfone resin, a polycarbonate resin, a polyamide resin, a polyimide resin, a polyolefin resin, an acrylic resin, a polyvinylchloride resin, a polystyrene resin, a polyvinyl alcohol resin, a polyarylate resin, a polyphenylene sulfide resin, a polyvinylidene chloride resin, and a (meth)acrylic resin. Among these, a polyester resin, a polycarbonate resin, a polyolefin resin, etc. are especially preferable.

The thickness of the transparent film substrate 1 is preferably about 2 to 300 μm, and more preferably 6 to 200 μm. When the thickness of the substrate is excessively small, the film is easily deformed due to the stress during feeding of the film. Therefore, the film quality of the transparent conductive layer formed thereon may deteriorate. On the other hand, when the thickness of the substrate is excessively large, a problem occurs such that the thickness of a device in which a touch panel, etc. is mounted becomes large.

From the viewpoint of suppressing the dimensional change when the heating and the crystallization are performed while feeding, under a prescribed tension, the film on which the indium composite oxide film is formed, a higher glass transition temperature of the substrate is preferable. On the other hand, as disclosed in JP-A-2000-127272, it tends to be difficult to promote the crystallization of the indium composite oxide film when the glass transition temperature of the substrate is high, and it may not be suitable for the crystallization by roll-to-roll. From such a viewpoint, the glass transition temperature of the substrate is preferably 170° C. or lower, and more preferably 160° C. or lower.

From the viewpoint of suppressing the elongation of the film by heating during the crystallization while the glass transition temperature is set in the above-described range, a film containing a crystalline polymer is preferably used as the transparent film substrate 1. The Young's modulus of the amorphous polymer film drastically decreases when it is heated to the vicinity of the glass transition temperature, and the plastic deformation of the amorphous polymer film occurs. For this reason, the elongation of the amorphous polymer film easily occurs when it is heated to the vicinity of the glass transition temperature under a feeding tension. Contrary to this, unlike the amorphous polymer, it is difficult to generate drastic deformation in a crystalline polymer film that is partially crystallized such as polyethylene terephthalate (PET) even when it is heated to the glass transition temperature or higher. For this reason, a film containing a crystalline polymer can be suitably used as the transparent film substrate 1 when the indium composite oxide film is crystallized while feeding the film under a prescribed tension as described later.

When the amorphous polymer film is used as the transparent film substrate 1, for example, a stretched film can be used to suppress the elongation at heating. That is, the stretched amorphous polymer film tends to shrink when it is heated to the vicinity of the glass transition temperature because the orientation of molecules is relieved. This thermal shrinkage and the elongation by the film feeding tension are balanced to suppress the deformation of the substrate when the indium composite oxide film is crystallized.

### (Anchor Layer)

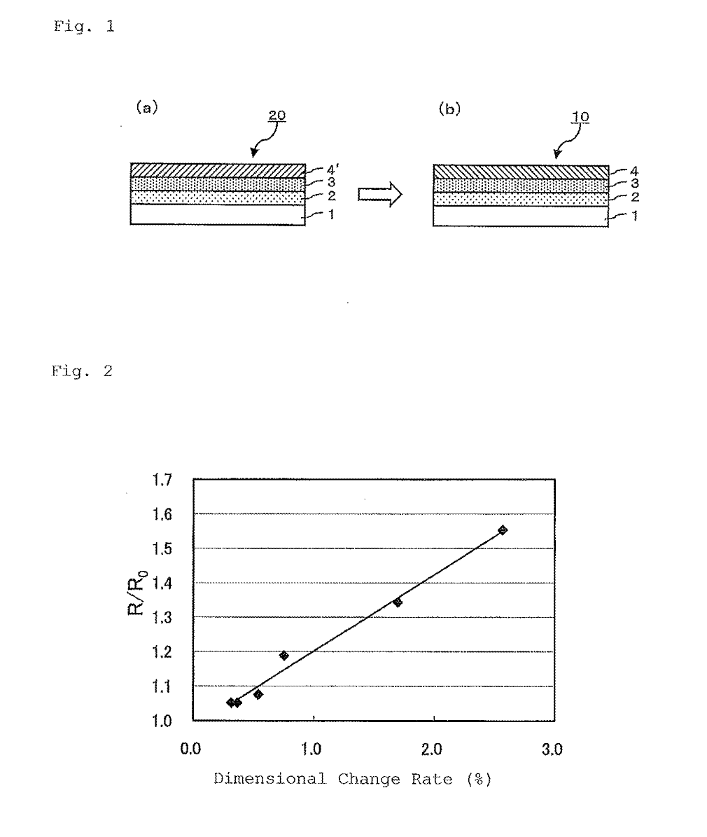

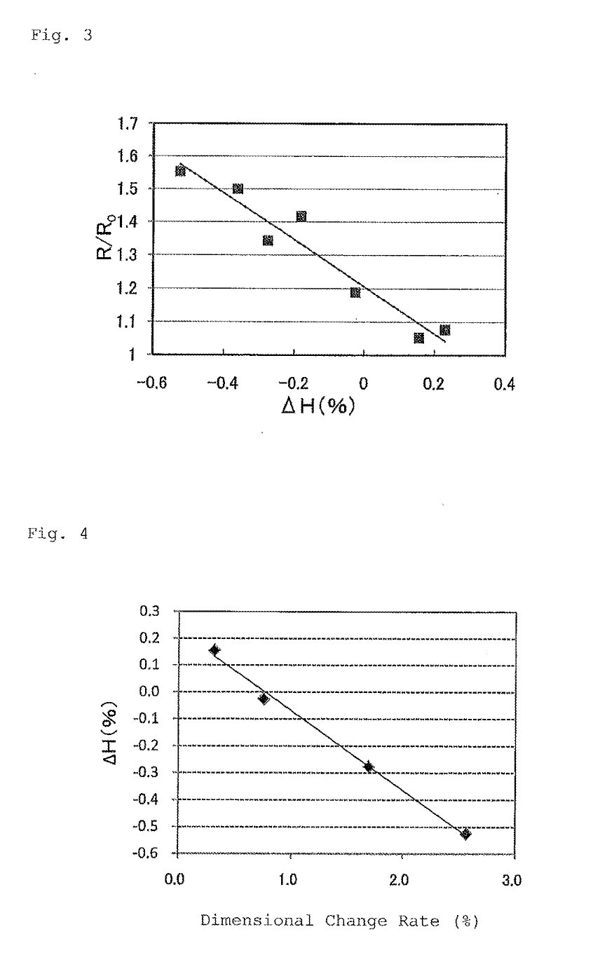

The anchor layers 2 and 3 may be provided on the main surface of the transparent film substrate 1 where the indium composite oxide film 4′ is formed for the purpose of improving adhesion between the substrate and the indium composite oxide film, controlling reflection characteristics, etc. The anchor layer may be a single layer or may be two layers or more as shown in FIG. 2. The anchor layer is formed from an inorganic substance, an organic substance, or a mixture of an inorganic substance and an organic substance. Preferred examples of the inorganic substance as a material to form the anchor layer include SiO₂, MgF₂, and Al₂O₃. Preferred examples of the organic substance include organic substances such as an acrylic resin, a urethane resin, a melamine resin, an alkyd resin, and a siloxane polymer. Especially, a thermosetting resin including a mixture of a melamine resin, an alkyd resin, and an organic silane condensate is preferably used as the organic substance. The anchor layer can be formed using the above-described material with a vacuum deposition method, a sputtering method, an ion plating method, a coating method, etc.

When the indium composite oxide film 4′ is formed, an appropriate adhesion treatment such as a corona discharge treatment, an ultraviolet ray irradiation treatment, a plasma treatment, or a sputter etching treatment can be performed on the substrate or the surface of the anchor layer in advance to improve the adhesion of the indium composite oxide.

### (Formation of Amorphous Film)

The amorphous indium composite oxide film 4′ is formed on the transparent film substrate with a gas phase method. Examples of the gas phase method include an electron beam vapor deposition method, a sputtering method, and an ion plating method. However, a sputtering method is preferable from the respect of obtaining a uniform thin film, and a DC magnetron sputtering method is suitably adopted. The “amorphous indium composite oxide” is not limited to be completely amorphous, and it may contain a small amount of crystalline component. Whether the indium composite oxide is amorphous or not is determined as follows: a laminate comprising a substrate and an indium composite oxide film formed on the substrate is immersed in hydrochloric acid having a concentration of 5 wt % for 15 minutes, it is washed and dried, and interterminal resistance between 15 mm is measured with a tester. Because the amorphous indium composite oxide film is etched by hydrochloric acid to be eliminated, the resistance increases when it is immersed in hydrochloric acid. In the present specification, the indium composite oxide film is considered to be amorphous when the interterminal resistance between 15 mm exceeds 10 kΩ after the film is immersed in hydrochloric acid, washed with water and dried.

From the viewpoint of obtaining the long amorphous laminate 20, the amorphous indium composite oxide film 4′ is preferably formed while feeding the substrate like as a roll-to-roll method. In the formation of the amorphous film by a roll-to-roll method, for example, sputtering is performed while sending out the substrate from the roll of the long substrate and allowing the substrate to run using a roll-up type sputtering apparatus, and the substrate on which the amorphous indium composite oxide film is formed is wounded up into a roll.

In the present invention, the amorphous indium composite oxide film 4′ that is formed on the substrate is preferably crystallized by heating for a short time. Specifically, the crystallization can be completed preferably within 60 minutes, more preferably within 30 minutes, and further preferably within 20 minutes when it is heated at 180° C. Whether the crystallization is completed or not can be determined from the interterminal resistance between 15 mm after the film is immersed in hydrochloric acid, washed with water, and dried in the same manner as in the determination of amorphous. When the interterminal resistance is within 10 kΩ, it is determined that the film is converted into a crystalline indium composite oxide.

As described above, the amorphous indium composite oxide film that can be crystallized by heating for a short time can be adjusted by, for example, the kind of a target that is used in sputtering, ultimate vacuum during sputtering, the flow rate of gas that is introduced during sputtering, etc.

A metal target (indium-tetravalent metal target) or a metal oxide target (In₂O₃-tetravalent metal target) is preferably used as the sputtering target. When the metal oxide target is used, the amount of the tetravalent metal oxide in the metal oxide target is preferably more than 0 and 15% by weight, more preferably 1 to 12% by weight, further preferably 6 to 12% by weight, still more preferably 7 to 12% by weight, further more preferably 8 to 12% by weight, still further more preferably 9 to 12% by weight, and especially preferably 9 to 10% by weight based on the total weight of In₂O₃ and the tetravalent metal oxide. In the case of reactive sputtering in which the In-tetravalent metal target is used, the amount of the tetravalent metal atom in the metal target is preferablymore than 0 and 15% by weight, more preferably 1 to 12% by weight, further preferably 6 to 12% by weight, still more preferably 7 to 12% by weight, further more preferably 8 to 12% by weight, still further preferably 9 to 12% by weight, and especially preferably 9 to 10% by weight based on the total weight of the In atom and the tetravalent metal atom. When the amount of the tetravalent metal or the tetravalent metal oxide in the target is too small, the durability of the indium composite oxide film may deteriorate. On the other hand, when the amount of the tetravalent metal or the tetravalent metal oxide is too large, the time that is required for the crystallization tends to become long. That is, the crystallization of the indium composite oxide tends to be hindered because the tetravalent metals except for those tetravalent metals that are incorporated in the In₂O₃ crystal lattice act as impurities. For this reason, the amount of the tetravalent metal or the tetravalent metal oxide is preferably in the above-described range.

Examples of the tetravalent metal that constitutes the indium composite oxide include Group 14 elements such as Sn, Si, Ge, and Pb; Group 4 elements such as Zr, Hf, and Ti; and Lanthanides such as Ce. Among these, Sn, Zr, Ce, Hf, and Ti are preferable from the viewpoint of allowing the indium composite oxide film to have low resistance, and Sn is the most preferable from the viewpoints of material cost and film forming property.

In the sputter film formation using such a target, first, the inside of the sputtering apparatus is vented to have a vacuum (ultimate vacuum) of preferably 1×10⁻³ Pa or less and more preferably 1×10⁻⁴ Pa or less, and then it is preferable to obtain an atmosphere in which impurities such as moisture in the sputtering apparatus and an organic gas that is generated from the substrate are removed. This is because the existence of the moisture or the organic gas terminates dangling bonds that are generated during the sputter film formation and prevents the crystal growth of the indium composite oxide. The ultimate vacuum can be improved (lower the pressure) to favorably crystallize the indium composite oxide even when the content of the tetravalent metal is high (for example, 6% by weight or more).

Next, oxygen gas that is a reactive gas is introduced in the thus vented sputtering apparatus as necessary together with an inert gas such as Ar, and the sputter film formation is performed. The introduced amount of the oxygen gas to the inert gas is preferably 0.1 to 15% by volume, and more preferably 0.1 to 10% by volume. The pressure during the film formation is preferably 0.05 to 1.0 Pa, and more preferably 0.1 to 0.7 Pa. When the pressure at the film formation is too high, the speed of film formation tends to decrease, and contrarily when the pressure is too low, the discharge tends to become unstable. The temperature at the sputter film formation is preferably 40 to 190° C., and more preferably 80 to 180° C. When the temperature at the film formation is too high, a poor outer appearance due to heat wrinkles and a thermal deterioration of the substrate film may occur. Contrarily, when the temperature at the film formation is too low, the film quality such as the transparency of the transparent conductive film may deteriorate.

The thickness of the indium composite oxide film can be appropriately adjusted so that the indium composite oxide film after crystallization has a desired resistance, and the thickness is preferably, for example, 10 to 300 nm, and more preferably 15 to 100 nm. When the thickness of the indium composite oxide film is small, a time that is required for the crystallization tends to become long, and when the thickness of the indium composite oxide film is large, the quality of the indium composite oxide film as a transparent conductive film for a touch panel may deteriorate in that the specific resistance after crystallization becomes too low and that the transparency decreases.

As described above, the amorphous laminate 20 in which the amorphous indium composite oxide film is formed on the substrate may be subjected to the crystallization step subsequently as it is or it may be wound into a roll by applying a prescribed tension around a core having a prescribed diameter as a center.

The thus obtained amorphous laminate is subjected to the crystallization step, and the amorphous indium composite oxide film 4′ is heated to be crystallized. When the amorphous laminate is subjected to the crystallization step as it is without being wound, the formation of the amorphous indium composite oxide film onto the substrate and the crystallization step are performed as a continuous series of steps. When the amorphous laminate is wound once, a step of continuously sending out a long amorphous laminate from the roll (film sending-out step) and a step of heating the amorphous laminate 20 that is sent out from the roll, while being fed, to crystallize the indium composite oxide film (crystallization step) are performed as a series of steps.

In the crystallization step, the amorphous laminate is heated while being fed under a prescribed tension, to crystallize the indium composite oxide film. From the viewpoint of obtaining the crystalline indium composite oxide film 4 having low resistance and excellent heating reliance, the dimensional change of the film in the crystallization step is preferably suppressed. Specifically, the change rate of the film length in the crystallization step is preferably +2.5% or less, more preferably +2.0% or less, further preferably +1.5% or less, and especially preferably +1.0% or less. The “film length” refers to the length in the film feeding direction (MD direction). The dimensional change of the film in the crystallization step can be obtained from the maximum value of the change rate of the film length in the crystallization step with the film length before the crystallization step as a standard.

The present inventors have formed an amorphous indium composite oxide film that can be completely crystallized in a short time on a biaxially orientated PET film under the sputtering conditions as described above to attempt the crystallization of the indium composite oxide film with a roll-to-roll method using the amorphous laminate. When the feeding speed of the film was adjusted so that the heating temperature was set to 200° C. and the heating time was set to 1 minute, thereby heating the amorphous laminate obtained by using an indium-tin composite oxide (ITO) as the amorphous indium composite oxide, an increase in transmittance was observed, and the ITO was crystallized. As described above, when the indium composite oxide film easily to be crystallized is used, the indium composite oxide film can be crystallized by heating at high temperature in a short time. It was confirmed that the crystallization can be performed continuously with a method of heating while feeding the film such as a roll-to-roll method.

On the other hand, it was found that the indium composite oxide film that was crystallized in such conditions may have largely increased resistance and insufficient heating reliance as compared to those of the indium composite oxide film in which the sheet was heated with a batch manner and crystallized. As a result of investigation on these causes, it was found that there is a certain correlation between the feeding tension of the transparent conductive laminate and the heating reliance of the crystalline indium composite oxide film when the indium composite oxide film is heated and crystallized, and that the feeding tension is made to be small to obtain a crystalline indium composite oxide film having higher heating reliance, that is, having a small change in a resistance value even by heating. Further, as a detailed investigation on the correlation between the tension and the resistance value or the heating reliance, the elongation in the film feeding direction caused by the feeding tension at the time of heating and crystallization was assumed to be a cause of an increase in resistance and a decrease in heating reliance.

The tensile test of the transparent conductive laminate on which the amorphous ITO was formed was performed at room temperature in order to investigate a relation between the elongation of the film and the quality of the indium composite oxide film. It was found that the resistance of the ITO film drastically increases when the elongation rate of the ITO film exceeds 2.5%. This is considered to be because the film disruption of the indium composite oxide film caused by large elongation rate occurred. On the other hand, the heating test by TMA was performed by adjusting a load so that the conditions become the same as those of the case where the resistance value increased to 3000 kΩ (Example 8 described later) when the crystallization of the ITO film was performed with a roll-to-roll method, and as a result, the elongation of the film was 3.0% As described above, the film disruption was considered to occur in the indium composite oxide film in Example 8 described later because the elongation of the film caused by the stress that is given to the transparent conductive laminate in the crystallization step exceeded 2.5%.

Therefore, when the elongation of the film exceeds 2.5% in any stages of the crystallization step, a state occurs in which the amorphous indium composite oxide film or the crystalline indium composite oxide film is elongated by 2.5% or more, and this is considered to lead to the film disruption.

Further, a relationship between the elongation rate by TMA and the resistance change of the crystalline indium composite oxide film was examined in order to investigate a relation between the elongation of the film and the quality of the indium composite oxide film. FIG. 2 is a graph in which the maximum value of the dimensional change rate when the amorphous laminate is heated under a prescribed load with a thermomechanical analysis (TMA) apparatus, and the resistance change of the indium composite oxide film that is heated and crystallized at the same tension and temperature condition as the TMA were plotted. An amorphous laminate was used in which an amorphous ITO film (weight ratio of indium oxide and tin oxide 97:3) having a thickness of 20 nm was formed on a biaxially oriented PET film having a thickness of 23 μm. The temperature rising condition of the TMA was 10° C./minute, and heating was performed from room temperature to 200° C. The resistance change is a ratio R/R₀ where R₀ is the surface resistance value of the ITO film that is heated and crystallized in the TMA apparatus and R is the surface resistance value of the ITO film after it is further heated at 150° C. for 90 minutes. As shown in FIG. 2, a linear relationship is observed between the maximum elongation rate during heating by the TMA and the resistance change R/R₀ of the indium composite oxide film, and the resistance change tends to become larger as the elongation rate is larger.

From the above-described results, from the viewpoint of suppressing an increase in the resistance value of the crystalline indium composite oxide film, the change rate of the film length after heating to the film length before heating is preferably +2.5% or less, and more preferably +2.0% or less, in the crystallization step. When the change rate of the film length is +2.5% or less, the resistance change R/R₀ of the crystalline indium composite oxide film upon heating at 150° C. for 90 minutes can be set to 1.5 or less to improve the heating reliance.

In the crystallization step in which under a tension the film is fed and heated, the length of the film changes depending on elastic deformation and plastic deformation due to the thermal expansion, thermal contraction, and stress of the substrate. However, because the temperature of the film decreases and the stress caused by the feeding tension is released after the crystallization step, the elongation caused by the elastic deformation due to the thermal expansion and the stress tends to be back to the original condition. For this reason, the change rate of the length of the film in the crystallization step is preferably obtained from the ratio of the circumference speed of a film feeding roll in the upstream side of the furnace and that of a film feeding roll in the downstream side of the furnace in order to evaluate the change rate. The change rate of the film length can be calculated from the TMA measurement instead of the ratio of the circumference speed of the roll. The amorphous laminate is cut out into a rectangle shape, and a load is adjusted so that the same stress as the feeding tension in the crystallization step can be given, whereby the change rate of the film length by the TMA can be measured.

In place of the change rate of the film length in the crystallization step, a thermal deformation history in the crystallization step can be also evaluated from a difference ΔH=(H₁−H₀) where H₀ is a dimensional change rate when the amorphous laminate before being subjected to the crystallization step is heated at 150° C. for 60 minutes and H₁ is a dimensional change rate when the transparent conductive laminate after crystallization is heated at 150° C. for 60 minutes. Two target points (scratches) are formed at an interval of about 80 mm in the MD direction on a sample that is cut out into a rectangle shape of 100 mm×10 mm having the MD direction as a long side, and the dimensional change rates H₀ and H₁ can be obtained from the following equation:

dimensional change rate (%)=100×(L₁−L₀)/L₀

where L₀ is a distance between the two points before heating and L₁ is a distance between the two points after heating.

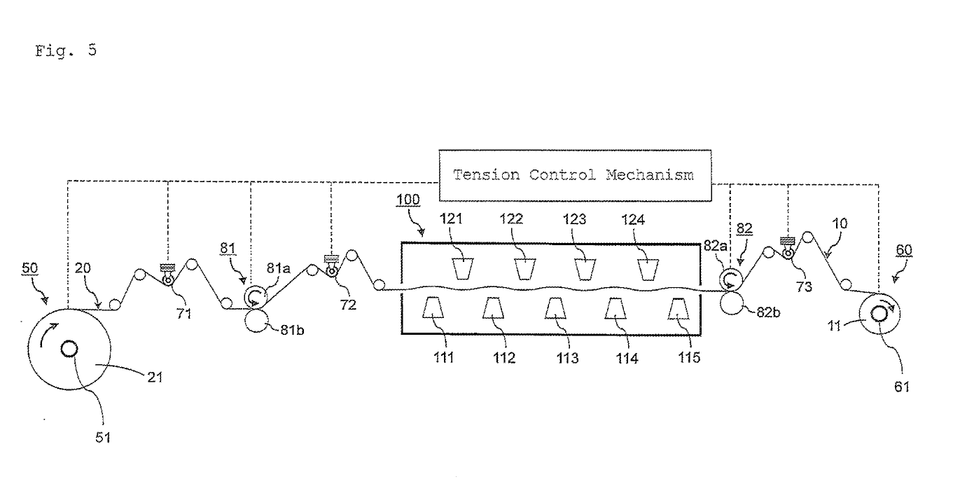

When ΔH is small and negative, it means that the elongation of the film by heating in the crystallization step is large. Therefore, it is considered that there is a correlation between ΔH and the elongation rate in the crystallization step. In order to investigate this, the feeding tension during heating was changed, and the crystallization of the ITO film was performed with a roll-to-roll method to obtain a difference ΔH of the dimensional change rates before and after the crystallization. A graph is shown in FIG. 3 in which the ratio R/R₀ where R₀ is the surface resistance value of the ITO film after crystallization and R is the surface resistance value of the ITO film after it is further heated at 150° C. for 90 minutes is plotted against ΔH. From FIG. 3, it is found that there is also a linear relationship between ΔH and R/R₀.

A graph is shown in FIG. 4 in which a relationship is plotted between the maximum value of the dimensional change rate when a load is adjusted and the heating test measurement is performed with TMA in the same manner as in FIG. 2 and ΔH. From FIG. 4, it is found that there is also a linear relationship between ΔH and the maximum value of the dimensional change rate with TMA. That is, when FIGS. 2 to 4 are unified comprehensively, it is found that there is a linear relationship mutually between the difference ΔH of the dimensional change rates before and after the crystallization, the maximum value of the dimensional change rate in the TMA heating test that is performed in the same stress condition as in the crystallization step, and the resistance change R/R₀ of the crystalline indium composite oxide film before and after heating. Therefore, it is found that the change rate of the film length in the crystallization step can be estimated from the value of ΔH and that the resistance change R/R₀ during heating the transparent conductive film is predictable.

When the correlation relationship between ΔH and R/R₀ as described above is taken into consideration, the difference ΔH=(H₁−H₀), where H₀ is a dimensional change rate when the amorphous laminate before being subjected to the crystallization step is heated at 150° C. for 90 minutes and H₁ is a dimensional change rate when the transparent conductive laminate after crystallization is heated at 150° C. for 90 minutes, is preferably −0.4 to +1.5%, more preferably −0.25 to +1.3%, and further preferably 0 to +1%. A small value of ΔH means that the elongation rate of the film in the crystallization step is large. When ΔH is smaller than −0.4%, the resistance value of the crystalline indium composite oxide tends to become large, and the heating reliance tends to decrease. On the other hand, when ΔH is larger than +1.5%, heat wrinkles tend to be easily generated caused by unstable feeding of the film, etc., and the outer appearance of the transparent conductive film may deteriorate.

The measurement of the dimensional change rate and the measurement by TMA can be also performed using only a substrate before the indium composite oxide film is formed instead of the transparent conductive laminate on which the indium composite oxide film is formed. The tension conditions that are suitable for the crystallization step can be estimated in advance by such measurements without actually performing the crystallization of the indium composite oxide film with a roll-to-roll method. That is, a general transparent conductive laminate comprises a substrate of about a few tens to 100 μm thick and an indium composite oxide film of about a few to a few tens nm thick formed thereon. When the ratio of both thicknesses is taken into consideration, the thermal deformation behavior of the laminate is dominant in the thermal deformation behavior of the substrate, and the presence or absence of the indium composite oxide film rarely affects the thermal deformation behavior. For this reason, when the TMA test of the substrate is performed, or the difference ΔH of the dimensional change rates before and after the substrate is heated under a prescribed stress is determined to evaluate the thermal deformation behavior of the substrate, the tension conditions that are suitable for the crystallization step can be estimated.

Below, the outline of the crystallization step will be described by way of an example in which a step of winding a long amorphous laminate 10 to form an amorphous roll 21 and continuously sending out a long amorphous laminate from the roll (film sending-out step) and a step of heating a long amorphous laminate 20 that is sent out from the roll, while being fed, to crystallize the indium composite oxide film (crystallization step) are performed as a series of steps with a roll-to-roll method.

FIG. 5 is one example of a manufacturing system to perform crystallization with a roll-to-roll method, and conceptually illustrates a step of crystallizing the indium composite oxide film.

The roll 21 of the amorphous laminate comprising the transparent film substrate and the amorphous indium composite oxide film formed on the transparent film substrate is set on a film sending-out mount 51 of a film feeding and heating apparatus having a furnace 100 between a film sending-out part 50 and a film winding part 60. The step of continuously sending out a long amorphous laminate from the roll 21 of the amorphous laminate (film sending-out step), the step of heating the long amorphous laminate 20 that is sent out from the roll 21, while being fed, to crystallize the indium composite oxide film (crystallization step), and a step of winding the crystalline laminate 10 after crystallization into a roll (winding step) are performed as a series of steps to crystallize the indium composite oxide film with a roll-to-roll method.

In the apparatus of FIG. 5, the long amorphous laminate 20 is continuously sent out from the roll 21 of the amorphous laminate that is set on the sending-out mount 51 of the sending-out part 50 (film sending-out step). The amorphous laminate that is sent out from the roll is heated in the furnace 100 that is provided in a film feeding path, while being fed, to crystallize the amorphous indium composite oxide film (crystallization step). The crystalline laminate 10 after heating and crystallization is wounded into a roll in the winding part 60 to form a roll 11 of the transparent conductive film (winding step).

A plurality of rolls are provided in the film feeding path between the sending-out part 50 and the winding part 60 to configure the film feeding path. Some of these rolls are made to be appropriate driving rolls 81a and 82a that link with a motor, etc. to give a tension to the film along with its rotation force and to feed the film continuously. In FIG. 5, the driving rolls 81a and 82a form rolls 81b and 82b and nip roll pairs 81 and 82, respectively. However, the driving rolls do not necessarily configure the nip roll pairs.

An appropriate tension detecting means, such as tension pickup rolls 71 to 73, is preferably provided on the feeding path. The rotating speed (peripheral speed) of the driving rolls 81a and 82a and the rotating torque of the winding mount 61 are controlled by an appropriate tension control mechanism so that a feeding tension that is detected by the tension detecting means becomes a prescribed value. For example, an appropriate means such as a combination of a dancer roll and a cylinder, in addition to the tension pickup roll, can be adopted as the tension detecting means.

As described above, the change rate of the film length in the crystallization step is preferably +2.5% or less. The change rate of the film length can be obtained from the ratio of the peripheral speed of the nip rolls 82 that are provided in the downstream side of the furnace to that of the nip rolls 81 that are provided in the upstream side of the furnace. In order to make the change rate of the film length within the above-described range, the driving of the rolls is controlled so that the ratio of the peripheral speed of the rolls in the downstream side of the furnace to that of the rolls in the upstream side of the furnace falls within the above-described range. On the other hand, the control can be performed so that the peripheral speed of the rolls becomes constant. However, in this case, defects may occur such that the film flaps during feeding, that the film sags in the furnace, etc. due to the thermal expansion of the film in the furnace 100.

From the viewpoint of obtaining the stable feeding of the film, a method can be adopted of controlling the peripheral speed of the driving roll 82a that is provided in the downstream side of the furnace so that the tension becomes constant in the furnace by the appropriate tension control mechanism. The tension control mechanism is a mechanism of performing a feedback to make the peripheral speed of the driving roll 82a small when a tension that is detected by the appropriate tension detecting means such as the tension pickup roll 72 is higher than a set value and to make the peripheral speed of the driving roll 82a large when the tension is larger than the set value. In FIG. 5, an example is shown in which the tension pickup roll 72 is provided as the tension detecting means in the upstream side of the furnace 100. However, the tension control means may be arranged in the downstream side of the furnace or may be arranged in both upstream and downstream sides of the furnace 100.

As such a manufacturing system, a system having a mechanism of heating the film while being fed such as a conventionally known film drying apparatus or a film stretching apparatus can be also diverted as it is. Alternatively, the manufacturing system can be also configured by diverting various configuration elements that are used in a film drying apparatus, a film stretching apparatus, etc.

The temperature inside the furnace 100 is adjusted to temperature that is suitable for crystallizing the amorphous indium composite oxide film. For example, it is adjusted to 120 to 260° C., preferably 150 to 220° C., and more preferably 170 to 220° C. When the temperature inside the furnace is too low, the productivity tends to deteriorate because the crystallization does not proceed or it takes a long time for crystallization. On the other hand, when the temperature inside the furnace is too high, the modulus (Young's modulus) of the substrate decreases and plastic deformation easily occurs. Therefore, the elongation of the film by the tension tends to easily occur. The temperature inside the furnace can be adjusted by an appropriate heating means such as an air circulation type thermostatic oven in which hot air or cold air circulates, a heater using a micro wave or far-infrared, a roll or a heat pipe roll heated for adjusting the temperature.

The heating temperature is not necessarily constant in the furnace, and it may have a temperature profile such that the temperature increases or decreases stepwisely. For example, the inside of the furnace is divided into a plurality of zones, and the preset temperature can be changed every each zone. From the viewpoints of preventing generation of wrinkles and generation of feeding defect caused by a drastic dimensional change of the film due to the temperature change at the inlet or outlet of the furnace, a preliminary heating zone and a cooling zone can be also provided so that the temperature change in the vicinity of the inlet or outlet of the furnace becomes moderate.

The heating time in the furnace is adjusted to a time that is suitable for crystallizing the amorphous film at the furnace temperature. For example, it is 10 seconds to 30 minutes, preferably 25 seconds to 20 minutes, and more preferably 30 seconds to 15 minutes. When the heating time is too long, the productivity may deteriorate and further the elongation of the film may easily occur. On the other hand, when the heating time is too short, the crystallization may be insufficient. The heating time can be adjusted by the length (the furnace length) of the film feeding path in the furnace and the feeding speed of the film.

An appropriate feeding method such as a roll feeding method, a float feeding method, or a tenter feeding method is adopted as a method for feeding the film in the furnace. From the viewpoint of preventing scratches of the indium composite oxide film due to rubbing in the furnace, a float feeding method or a tenter feeding method that is non-contacting feeding methods can be suitable adopted. A float feeding type furnace is shown in FIG. 5 in which hot air blowing nozzles (floating nozzles) 111 to 115 and 121 to 124 are alternatively arranged on the upper side and bottom side of the film feeding path.

In the case of adopting a float feeding method as the feeding of the film in the furnace, when the feeding tension in the furnace is too small, the film rubs against the nozzles due to flapping of the film or sagging of the film by its weight. Therefore, scratches may be generated on the surface of the indium composite oxide film. It is preferable to control the flow amount of the hot air and the feeding tension in order to prevent such scratches.

When a method for feeding the film with the feeding tension given in the MD direction such as a roll feeding method or a float feeding method is adopted, the feeding tension is preferably adjusted so that the elongation rate of the film falls within the above-described range. The preferable range of the feeding tension differs depending on the thickness of the substrate, Young's modulus, a linear expansion coefficient, etc. However, when a biaxially oriented polyethylene terephthalate film is used as the substrate for example, the feeding tension per unit width of the film is preferably 25 to 300 N/m, more preferably 30 to 200 N/m, and further preferably 35 to 150 N/m. The stress that is given to the film during feeding is preferably 1.1 to 13 MPa, more preferably 1.1 to 8.7 MPa, and further preferably 1.1 to 6.0 MPa.

When a tenter feeding method is adopted for feeding the film in the furnace, any of a pin tenter method and a clip tenter method can be adopted. Because the tenter feeding method is a method for feeding the film without giving a tension in the feeding direction of the film, it can be said that the tenter feeding method is a suitable feeding method from the viewpoint of suppressing the dimensional change in the crystallization step. On the other hand, when expansion of the film due to heating occurs, a distance between clips (or a distance between pins) in the transverse direction may be extended to absorb the sagging. However, when the distance between clips is excessively extended, the resistance of the crystalline indium composite oxide film may increase and the heating reliance may deteriorate due to the stretching of the film in the transverse direction. From such a viewpoint, the distance between clips is preferably adjusted so that the elongation rate of the film in the transverse direction (TD) is adjusted to preferably +2.5% or less, more preferably +2.0% or less, further preferably +1.5% or less, and especially preferably +1.0% or less.

The crystalline laminate 10 in which the indium composite oxide film is crystallized by heating in the furnace is fed to the winding part 60. A core having a prescribed diameter is set on the winding mount 61 of the winding part 60, and the crystalline laminate 10 is wound into a roll with a prescribed tension around this core as a center to obtain the roll 11 of the transparent conductive film. The tension (winding tension) that is given to the film when it is wound around the core is preferably 20 N/m or more, and more preferably 30 N/m or more. When the winding tension is too small, the film may not be wound well around the core and scratches may occur on the film due to a winding shift.

In general, the preferred range of the winding tension is often large as compared to the film feeding tension to suppress the elongation of the film in the crystallization step. From the viewpoint of making the winding tension larger than the film feeding tension, it is preferable to provide a tension cutting means in the feeding path between the furnace 100 and the winding part 60. As the tension cutting means, a suction roll, rolls arranged so that the film feeding path is like the letter S, etc., in addition to the nip rolls 82 shown in FIG. 5, can be used. The tension detecting means such as the tension pickup roll 72 is arranged between the tension cutting means and the winding part 60, and the rotating torque of the winding mount 61 is preferably adjusted by the appropriate tension control means so that the winding tension becomes constant by the appropriate tension control mechanism.

A case has been described as an example above in which the crystallization of the indium composite oxide film is performed with a roll-to-roll method. However, the present invention is not limited to such a step, and the formation and crystallization of the amorphous laminate may be performed as a series of steps as described above. Other steps such as forming other layers on the crystalline laminate may be provided after the crystallization step and before the formation of the roll 11.

According to the present invention, an amorphous indium composite oxide film is formed in which the crystallization of the film can be completed by heating in a short time as described above. For this reason, the time required for the crystallization is shortened, and the crystallization of the indium composite oxide film can be performed with a roll-to-roll method, thereby obtaining a roll of a long transparent conductive film on which the crystalline indium composite oxide film is formed. Because the elongation of the film in the crystallization step is suppressed, a transparent conductive film can be obtained in which a crystalline indium composite oxide film having small resistance and an excellent heating reliance is formed. The ratio R/R₀ of the surface resistance value R of the indium composite oxide film before and after heating the transparent conductive film at 150° C. for 90 minutes is preferably 1.0 or more and 1.5 or less, more preferably 1.4 or less, and further preferably 1.3 or less.

A transparent conductive film thus obtained can be suitably used in a transparent electrode of various apparatuses and formation of a touch panel. According to the present invention, a roll of a long transparent conductive film on which the crystalline indium composite oxide film is formed can be obtained. Therefore, lamination and processing of a metal layer, etc. can be performed with a roll-to-roll method even in a step of forming a touch panel, etc. afterwards. For this reason, according to the present invention, not only the productivity of the transparent conductive film itself improves, but also the productivity of a touch panel, etc. afterwards can also improve.

### EXAMPLES

The present invention will be described below by way of examples. However, the present invention is not limited to the following examples.

### [Evaluation Method]

The evaluations in the examples were performed with the following methods.

### <Resistance>

The surface resistance was measured with a four-terminal method according to JIS K7194 (1994). A film piece was cut out from a transparent conductive film after crystallization, and it was heated in a heating bath at 150° C. for 90 minutes to obtain a ratio R/R₀ of the surface resistance (R) after heating to the surface resistance (R₀) before heating.

### <Dimensional Change Ratio>

A 100 mm×10 mm rectangular test piece having the MD direction as a long side was cut out from an amorphous laminate before being subjected to a crystallization step, and two target points (scratches) were formed with an interval of about 80 mm in the MD direction to measure a distance L₀ between the target points with a three-dimensional length measurement machine. Then, the test piece was heated in a heating bath at 150° C. for 90 minutes to measure a distance L₁ between target points after heating. A dimensional change rate H₀(%)=100×(L₁−L₀)/L₀ was calculated from L₀ and L. Also, for a crystalline laminate after crystallization, the dimensional change rate H₁ was also obtained in the same manner, and the difference ΔH=(H₁−H₀) of the dimensional change rates before and after crystallization was calculated from the difference of these dimensional change rates.

### <Transmittance>

A whole light transmittance was measured using a haze meter (manufactured by Suga Test Instruments Co., Ltd.) according to JIS K-7105.

### <Confirmation of Crystallization>

A laminate comprising a substrate and an amorphous indium composite oxide film formed on the substrate was placed in a heating oven at 180° C., and regarding each laminate that was kept in the oven for 2 minutes, 10 minutes, 30 minutes, and 60 minutes after the laminate was placed in the oven, the resistance value after the laminate was immersed in hydrochloric acid was measured with a tester to determine the completion of the crystallization.

### <Tension and Elongation Rate>

As a tension in the crystallization step, a value was used which was detected by a tension pickup roll that was provided in the upstream of a furnace in a film feeding path. A stress given to a film was calculated from the tension and the thickness of the film. The elongation rate of the film in the crystallization step was calculated from the ratio of the peripheral speed of a driving nip roll provided in the upstream of the furnace in the film feeding path and that of a driving nip roll provided in the downstream of the furnace.

### Example 1

### Formation of the Anchor Layer

Two undercoat layers were formed on a biaxially oriented polyethylene terephthalate film (trade name “Diafoil” manufactured by Mitsubishi Plastics, Inc., glass transition temperature 80° C., refractive index 1.66) having a thickness of 23 μm with a roll-to-roll method. A thermosetting resin composition containing a melamine resin, an alkyd resin, and an organic silane condensate at a weight ratio of 2:2:1 in solid content was diluted with methylethylketone so that the concentration of the solid content was 8% by weight. This solution was applied on one of the main surfaces of a PET film, and it was heated and cured at 150° C. for 2 minutes to form a first undercoat layer having a thickness of 150 nm and a refractive index of 1.54.

A siloxane thermosetting resin (“Colcoat P” manufactured by COLCOAT CO., LTD.) was diluted with methylethylketone so that the concentration of solid content was 1% by weight. This solution was applied onto the first undercoat layer, and it was heated and cured at 150° C. for 1 minute to form a SiO₂ thin film (second undercoat layer) having a thickness of 30 nm and a refractive index of 1.45.

### (Formation of Amorphous ITO Film)

A sintered body containing indium oxide and tin oxide at a weight ratio of 97:3 was loaded as a target material in a parallel plate winding type magnetron sputtering apparatus. While feeding the PET film substrate on which the two undercoat layers were formed, dehydration and degassing were performed and the apparatus was vented so as to have 5×10⁻³ Pa. In this state, the heating temperature of the substrate was set to 120° C., and argon gas and oxygen gas were introduced at a flow ratio of 98%:2% so that the pressure was 4×10⁻¹ Pa, and a DC sputtering method was performed to form an amorphous ITO film having a thickness of 20 nm on the substrate. The substrate on which the amorphous ITO film was formed was continuously wounded around a core to form a roll of an amorphous laminate. The surface resistance of the amorphous ITO film was 450Ω/□. A heating test of the amorphous ITO film was performed to confirm that crystallization was completed after heating at 180° C. for 10 minutes.

### (Crystallization of ITO Film)

Using a film heating and feeding apparatus having a float feeding type furnace as shown in FIG. 5, a laminate was continuously sent out from the roll of the amorphous laminate, and it was heated in a furnace, while being fed, to crystallize the ITO film. The laminate after crystallization was wound again around the core to form a roll of a transparent conductive film on which the crystalline ITO film was formed.

In the crystallization step, the length of the furnace was 20 m, the heating temperature was 200° C., and the feeding speed of the film was 20 m/minute (heating time when the film was passing through the inside of the furnace: 1 minute). The feeding tension in the furnace was set so that the tension per unit width of the film was 28 N/m. The transmittance of the obtained transparent conductive film increased as compared to the amorphous ITO film before heating, and crystallization was confirmed. It was also confirmed that the crystallization was completed from the resistance value after the film was immersed in hydrochloric acid.

### Example 2

In Example 2, a roll of a transparent conductive film on which a crystalline ITO film was formed was formed in the same manner as in Example 1. However, it was different from Example 1 only in a respect that the feeding tension per unit width of the film in the furnace in the crystallization step was set to 51 N/m.

### Example 3

In Example 3, a roll of a transparent conductive film on which a crystalline ITO film was formed was formed in the same manner as in Example 1. However, it was different from Example 1 only in a respect that the feeding tension per unit width of the film in the furnace in the crystallization step was set to 65 N/m.

### Example 4

In Example 4, a roll of a transparent conductive film on which a crystalline ITO film was formed was formed in the same manner as in Example 1. However, it was different from Example 1 only in a respect that the feeding tension per unit width of the film in the furnace in the crystallization step was set to 101 N/m.

### Example 5

In Example 5, a transparent conductive laminate in which an amorphous ITO film was formed on a biaxially oriented polyethylene terephthalate film on which an undercoat layer was formed was obtained in the same sputtering conditions as in Example 1 except that a sintered body containing indium oxide and tin oxide at a weight ratio of 90:10 was used as a target material and the apparatus was vented so as to have 5×10⁻⁴ Pa during the dehydration and degassing before sputtering. The surface resistance of the amorphous ITO film was 450Ω/□. A heating test of the amorphous ITO film was performed to confirm that crystallization was completed after heating at 180° C. for 30 minutes.

The crystallization of ITO was performed using this amorphous laminate with a roll-to-toll method in the same manner as in Example 1. However, the conditions of the crystallization step were different from those of Example 1 in respects that the feeding speed of the film was changed to 6.7 m/minute (heating time when the film was passing through in the furnace: 3 minutes) and that the feeding tension was set to 65 N/m. The transmittance of the obtained transparent conductive film increased as compared to that of the amorphous laminate before heating, and it was confirmed that the laminate was crystallized. It was also confirmed that the crystallization was completed from the resistance value after the film was immersed in hydrochloric acid.

### Example 6

In Example 6, a transparent conductive laminate in which an amorphous ITO film was formed on a biaxially oriented polyethylene terephthalate film on which an undercoat layer was formed was obtained in the same sputtering conditions as in Example 1 except that the apparatus was vented so as to have 5×10⁻⁴ Pa during the dehydration and degassing before sputtering. The surface resistance of the amorphous ITO film was 450Ω□. A heating test of the amorphous ITO film was performed to confirm that crystallization was completed after heating at 180° C. for 2 minutes.

The crystallization of ITO was performed using this amorphous laminate with a roll-to-toll method in the same manner as in Example 1. However, the conditions of the crystallization step were different from those of Example 1 in a respect that the feeding tension was set to 101 N/m. The transmittance of the obtained transparent conductive film increased as compared to that of the amorphous laminate before heating, and it was confirmed that the laminate was crystallized.

### Example 7

In Example 7, a roll of a transparent conductive film on which a crystalline ITO film was formed was formed in the same manner as in Example 6. However, it was different from Example 6 only in a respect that the feeding tension per unit width of the film in the furnace in the crystallization step was set to 120 N/m.

### Example 8

In Example 8, a roll of a transparent conductive film on which a crystalline ITO film was formed was formed in the same manner as in Example 1. However, it was different from Example 1 only in a respect that the feeding tension per unit width of the film in the furnace in the crystallization step was set to 138 N/m.

The manufacturing conditions, and evaluation results of the transparent conductive film of each Example are shown in Table 1. In Examples 1 to 8, the characteristics of the transparent conductive film after crystallization in the inner circumference part (around core) and outer circumference part of the roll were equal.

TABLE 1

| | Formation of | | | | | | | | | | | |
|---|---|---|---|---|---|---|---|---|---|---|---|---|
| | Amorphous ITO | | | | | | | | | | | |
| | SnO₂ (% | Ultimate | Heating Conditions | | | | | | Characteristics after Crystallization | | | |
| | by | Vacuum | Heating | Temperature | Time | Tension | Stress | Elongation | Resistance | | Transmittance | |
| | weight) | (Pa) | Method | (° C.) | (minute) | (N/m) | (MPa) | Rate (%) | Ω/□ | ΔH | (%) | R/R_{∘} |
| Example | 3 | 5 × 10⁻³ | Feeding | 200 | 1 | 28 | 1.2 | 0.30 | 300 | 0.30 | 89.5 | 1.01 |
| 1 | | | | | | | | | | | | |
| Example | 3 | 5 × 10⁻³ | Feeding | 200 | 1 | 51 | 2.2 | 0.32 | 300 | 0.16 | 89.5 | 1.03 |
| 2 | | | | | | | | | | | | |
| Example | 3 | 5 × 10⁻³ | Feeding | 200 | 1 | 65 | 2.8 | 0.75 | 300 | −0.03 | 89.5 | 1.19 |
| 3 | | | | | | | | | | | | |
| Example | 3 | 5 × 10⁻³ | Feeding | 200 | 1 | 101 | 4.4 | 1.95 | 300 | −0.36 | 89.5 | 1.40 |
| 4 | | | | | | | | | | | | |
| Example | 10 | 5 × 10⁻⁴ | Feeding | 200 | 3 | 65 | 2.8 | 0.75 | 150 | −0.02 | 89.5 | 1.20 |
| 5 | | | | | | | | | | | | |
| Example | 3 | 5 × 10⁻⁴ | Feeding | 200 | 1 | 101 | 4.4 | 1.95 | 300 | −0.35 | 89.5 | 1.45 |
| 6 | | | | | | | | | | | | |
| Example | 3 | 5 × 10⁻⁴ | Feeding | 200 | 1 | 120 | 5.2 | 2.57 | 300 | −0.52 | 89.5 | 1.60 |
| 7 | | | | | | | | | | | | |
| Example | 3 | 5 × 10⁻³ | Feeding | 200 | 1 | 138 | 6.0 | 2.96 | 3000 | −0.70 | 89.5 | — |
| 8 | | | | | | | | | | | | |

As described above, it is found that in Examples 1 to 8 the indium composite oxide film can be crystallized by heating while feeding the film.

Comparing the respective Examples, when the tension (stress) in the crystallization step is made small, it is found that the elongation during the step is suppressed, and that the change (R/R₀) of the resistance value in the heating test is small accordingly. Especially, as the sputtering conditions, a target having a less content of a tetravalent metal is used or the ultimate vacuum is increased (brought to near vacuum), it is found that an amorphous ITO film which is more easily crystallized can be obtained, and thus the heating time in the crystallization step can be reduced to thereby improve the productivity.

### DESCRIPTION OF REFERENCE SIGNS

1 Transparent Film Substrate
2, 3 Anchor Layer
4 Crystalline Film
4′ Amorphous Film
10 Crystalline Laminate (Transparent Conductive Film)
20 Amorphous Laminate
50 Sending-Out Part
51 Sending-Out Mount
60 Winding Part
61 Winding Mount
71 to 73 Tension Pickup Roll
81, 82 Nip Roll Pair
81a Driving Roll
82a Driving Roll
100 Furnace

1. A method for manufacturing a long transparent conductive film comprising a long transparent film substrate and a crystalline indium composite oxide film formed on the long transparent film substrate, the method comprising:
an amorphous laminate formation step of forming an amorphous film of an indium composite oxide containing indium and a tetravalent metal on the long transparent film substrate with a sputtering method, and
a crystallization step of continuously feeding the long transparent film substrate on which the amorphous film is formed into a furnace and crystallizing the amorphous film, wherein
the indium composite oxide contains more than 0 parts by weight and 15 parts by weight or less of the tetravalent metal based on 100 parts by weight of the total of indium and the tetravalent metal.

2. The method for manufacturing a transparent conductive film according to claim 1, wherein the inside of a sputtering machine is vented to have a vacuum of 1×10⁻³ Pa or less before the amorphous film is formed in the amorphous laminate formation step.

3. The method for manufacturing a transparent conductive film according to claim 1, wherein, in the crystallization step, the temperature inside the furnace is 120 to 260° C., and the heating time is 10 seconds to 30 minutes.

4. The method for manufacturing a transparent conductive film according to claim 1, wherein the stress in the feeding direction that is given to the long transparent film substrate in the furnace in the crystallization step is 1.1 to 13 MPa.
